(19) United States
(12) Patent Application Publication
(10) Pub. No.: US 2006/0183301 A1
(43) Pub. Date: Aug. 17, 2006

(54) Method for forming thin film

(76) Inventors: Seung-Jin Yeom, Ichon-shi (KR); Deok-Sin Kil, Ichon-shi (KR); Kwon Hong, Ichon-shi (KR); Jae-Sung Roh, Ichon-shi (KR)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/321,538

(22) Filed: Dec. 30, 2005

(30) Foreign Application Priority Data
Feb. 16, 2005 (KR) 2005-0012677

(51) Int. Cl. H01L 21/20

(52) U.S. Cl. 438/478

(57) ABSTRACT

A method for forming a thin film by using an atomic layer deposition (ALD) method and a method for fabricating a capacitor using the same includes: supplying a source gas, a reaction gas, and a purge gas, then discontinuing the supply of the reaction gas and the source gas, followed by supplying and then discontinuing the supply of the reaction gas, wherein supplying the source gas, the reaction gas, and the purge gas, then discontinuing the supply of the reaction gas and the source gas, followed by supplying and then discontinuing the supply of the reaction gas constitutes a unit cycle, and repeating the unit cycle until a thin film having a desired thickness is deposited.

The present application claims the benefit of priority of Korean patent application No. KR 2005-0012677, filed in the Korean Patent Office on Feb. 16, 2005, the entire contents of which are incorporated herein by reference.

### TECHNICAL FIELD

The present invention relates to a technology of fabricating a semiconductor device; and more particularly, to a method for forming a thin film using an atomic layer deposition (ALD) method and a method for fabricating a capacitor using the same.

### DESCRIPTION OF RELATED ARTS

As the scale of integration of dynamic random access memory (DRAM) devices has been recently increasing, DRAM devices have been influenced by a gradual reduction of a capacitor size and thus, it has been hard to secure a required dielectric capacitance. To secure the required dielectric capacitance, a thickness of a dielectric thin film should be reduced or a material with a large dielectric constant should be applied.

In DRAM devices having a size equal to or less than 80 nm, a technology applying a stack layer of hafnium oxide (HfO₂) and aluminum oxide (Al₂O₃) has been developed to secure both a minimum leakage current and a sufficient dielectric capacitance. A concave type dielectric structure with the stack layer has reached a limit in securing a sufficient dielectric capacitance. To alleviate the shortcomings of a concave type dielectric structure, a cylinder type structure may be applied to secure the capacitor size. However, although a cylinder type structure is formed by using a storage node formed from titanium nitride (TiN), an effective thickness of the dielectric layer has a limit of about 11 Å. In devices with a size equal to and less than 65 nm, an effective thickness of the dielectric layer should be equal to or less than 10 Å to secure the dielectric capacitance. Hence, the introduction of a metal electrode selected from a group consisting of ruthenium (Ru), praseodymium (Pr), and iridium (Ir) is required.

When a storage node is used as the metal electrode, high layer density is necessary to avoid agglomeration. In addition, step coverage should be more than 80%.

If Ru is deposited on a metal storage node by using a conventional chemical vapor deposition (CVD) method, the deposited thin film may contain impurities such as carbon (C), hydrogen (H), and oxygen (O). Ru also has a low density of approximately 7 g/cm³, in contrast with a density of bulk Ru of approximately 12.2 g/cm³; and a density of PVD Ru of approximately 11.9 g/cm³. The impurities and low density of the deposited Ru may increase agglomeration, and lead to an unstable capacitance. As for the step coverage, in the devices with a size equal to or less than 65 nm, it is difficult to obtain a critical dimension (CD) of a contact for forming the storage node equal to or less than 100 nm and an having aspect ratio of 20 to 1.

To alleviate these problems, an ALD method using a surface reaction is used to deposit metal films. The ALD method eliminates the above problems associated with step coverage and agglomeration.

FIG. 1 is a graph illustrating a sequence over time of supplying gas to a chamber as used in a typical ALD method having a self-surface reaction limited mechanism.

After a wafer is loaded into a chamber, a source gas and a purge gas are simultaneously supplied to the inside of the chamber, inducing a chemical adsorption of the source gas on a surface of the wafer.

While continuing to supply the purge gas, the supply of the source gas is discontinued. This steps serves to remove non-adsorbed/reacted parts of the source gas or any remaining reaction byproducts.

Subsequently, while continuing to supply the purge gas into the chamber, a reaction gas is supplied into the chamber and reacts with chemically adsorbed parts of the source gas on the surface of the wafer, thereby forming an atomic layer.

Next, while continuing to supply the purge gas into the chamber, the supply of the reaction gas is discontinued. As with the second step, this step serves to remove remaining non-reacted parts of the reaction gas and any remaining reaction byproducts.

The above described four steps comprise a unit cycle of the ALD method. The unit cycle is repeatedly performed to form a thin film with having a desired thickness.

Since the ALD method uses the self-surface reaction limited mechanism, it is possible to control a thickness of the thin film in an atomic layer unit, and it is also possible to deposit the thin film regardless of the topology of a lower structure. Thus, a conformal and uniform thin film can be obtained. In addition, because the source gas and the reaction gas are isolated from each other by supplying the source gas and the reaction gas in separate steps with the inert purge gas used to remove any non-reacted parts of the source and reaction gases, the ALD method can better prevent particle generation resulting from a gas phase reaction, when compared to the traditional CVD method.

FIGS. 2A and 2B are graphs illustrating sequences over time of supplying gas to a chamber as used in a typical plasma enhanced atomic layer deposition (PEALD) method.

After a wafer is loaded into a chamber, a source gas and a purge gas are simultaneously supplied into the chamber, inducing chemical adsorption of the source gas on a surface of the wafer.

Next, while continuing to supply the purge gas to the chamber, the supply of the source gas is discontinued. The continuous supply of the purge gas in this step serves to remove non-adsorbed/reacted parts of the source gas or reaction byproducts.

Then, while continuing the supply of the purge gas into the chamber, a reaction gas is simultaneously supplied into the chamber. At the same time, plasma is supplied into the chamber. The reaction gas reacts with chemically adsorbed parts of the source gas on the surface of the wafer, depositing a thin film.

Subsequently, while continuing to supply the purge gas to the chamber, the supply of the reaction gas is discontinued. The continuous supply of the purge gas serves to remove remaining non-reacted pats of the reaction gas and reaction byproducts.

As above, these steps are considered as a unit cycle of the ALD method. The unit cycle is repeatedly performed until a thin film with a desirable thickness is formed.

Next, FIG. 2B illustrates a sequence over time of supplying gas in a PEALD method when the source gas and reaction gas do not react. Because the source gas and the reaction gas do not react with each other, the reaction gas is supplied continuously as a purge gas. However, at a desirable time after the source gas is discontinued, a plasma is provided for a period of time to induce the reaction.

The method shown in FIG. 2B may reduce the time needed to complete the purge step in comparison to the method shown in FIG. 2A.

FIG. 3 illustrates the supply of gas over time used when plasma treatment is the last step of the unit cycle of the ALD method shown in FIG. 1 or the PEALD method shown in FIGS. 2A and 2B.

A wafer is loaded into a chamber. Afterwards, a source gas and a purge gas are simultaneously supplied into the chamber, inducing chemical adsorption of the source gas on a surface of the wafer.

Next, while continuing the supply of the purge gas, the supply of the source gas is discontinued.

Next, while continuing to supply the purge gas into the chamber, a reaction gas is simultaneously supplied to the chamber, and a plasma can be added at the same time. The reaction gas reacts with chemically adsorbed parts of the source gas on the surface of the wafer depositing a thin film.

Subsequently, while continuing to supply the purge gas, the supply of the reaction gas is discontinued. The continuous supply of the purge gas serves to remove remaining non-reacted pats of the reaction gas and reaction byproducts. Afterwards, while continuing to supply the purge gas to the chamber, a gas for plasma treatment is simultaneously supplied to the chamber. The gas for plasma treatment may be ammonium (NH₃) or hydrogen (H₂) for the purpose of removing C and O and other impurities, and for improving a surface quality and step coverage of the thin film.

The above ALD method including the plasma treatment improves the film quality, but has a long unit cycle and decreases the thin film deposition rate. The above ALD method or PEALD method allows for the formation of a uniform thin film having a high aspect ratio at a low pressure.

The ALD method can achieve deposition rate per cycle ranging from approximately 0.5 Å to approximately 1 Å, with a required time per cycle ranging from approximately 1 second to approximately 10 seconds, thereby providing a deposition rate of approximately 6 Å per minute. Thus, if Ru is deposited to a thickness of 200 Å, it is hard to deposit two sheets of a wafer per hour. Accordingly, the ALD method has a relatively poor throughput.

### SUMMARY

Consistent with the present invention, there is provided a method for depositing a thin film suitable for improving a deposition rate of the thin film without degrading the properties of the thin film .

In accordance with one aspect consistent with the present invention, there is provided a method for depositing a thin film on a substrate, comprising: supplying a source gas, a reaction gas, and a purge gas; discontinuing the supply of the source gas and the reaction gas; supplying the reaction gas; discontinuing the supply of the reaction gas, wherein supplying the source gas, the reaction gas, and the purge gas, discontinuing the supply of the source gas and the reaction gas, supplying the reaction gas, and discontinuing the supply of the reaction gas constitutes a unit cycle; and repeating the unit cycle until a thin film having a desired thickness is formed.

In accordance with another aspect consistent with the present invention, there is provided a method for depositing a thin film on a substrate, comprising: supplying a purge gas, and a source gas; supplying a reaction gas and discontinuing the supply of the source gas, wherein supplying the purge gas, and the source gas, and supplying a reaction gas and discontinuing the supply of the source gas constitutes a unit cycle; and repeating the unit cycle until a thin film having a desired thickness is formed.

In accordance with a further aspect consistent with the present invention, there is provided a method for depositing a thin film on a substrate, comprising: supplying a source gas, a reaction gas and a purge gas; discontinuing the supply of the source gas, wherein supplying the source gas, the reaction gas and the purge gas, and discontinuing the supply of the source gas constitutes a unit cycle; and repeating the unit cycle until a thin film having a desired thickness is formed.

In accordance with still further aspect consistent with the present invention, there is provided a method for depositing a thin film on a substrate, comprising the steps of: supplying a source gas, a reaction gas and a purge gas; discontinuing the supply of the reaction gas, wherein supplying the source gas, the reaction gas and the purge gas, and discontinuing the supply of the reaction gas constitutes a unit cycle; and repeating the unit cycle until a thin film having a desired thickness is formed.

### BRIEF DESCRIPTION OF THE DRAWINGS

The following description of the embodiments given in conjunction with the accompanying drawings, in which:

FIG. 1 is a graph illustrating a sequence of gas supply for a typical atomic layer deposition (ALD) method;

FIGS. 2A and 2B are graphs illustrating sequences of gas supplies for a typical plasma enhanced atomic layer deposition (PEALD) method;

FIG. 3 is a graph illustrating a typical ALD or a PEALD method additionally including a plasma treatment within a unit cycle;

FIGS. 4 to 7 are graphs illustrating various embodiments of a method for depositing a thin film consistent with the present invention; and

FIGS. 8A to 8E are cross-sectional views illustrating a method for fabricating a capacitor using the method for depositing the thin film shown in FIGS. 4 to 7.

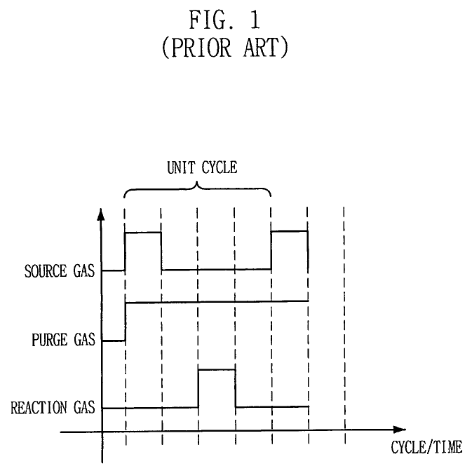

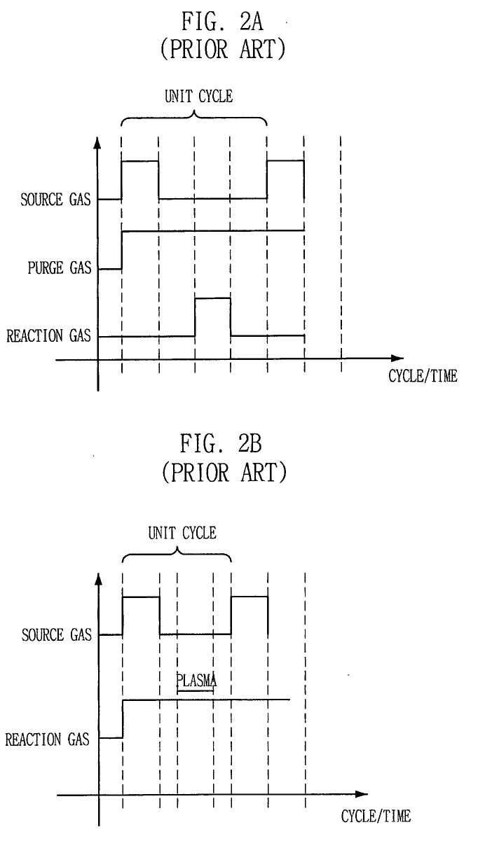

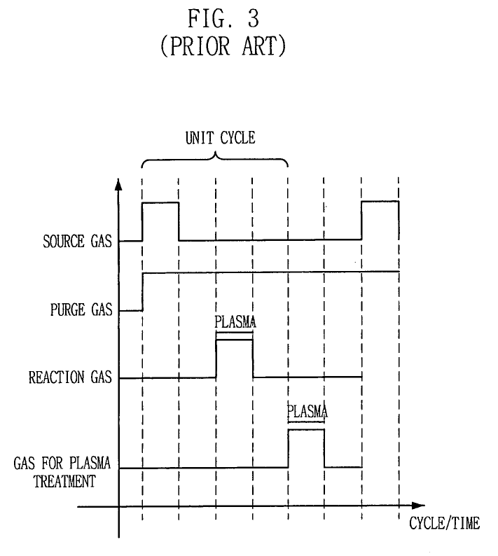

### DETAILED DESCRIPTION

Hereinafter, detailed descriptions on certain embodiments consistent with the present invention will be provided with reference to the accompanying drawings.

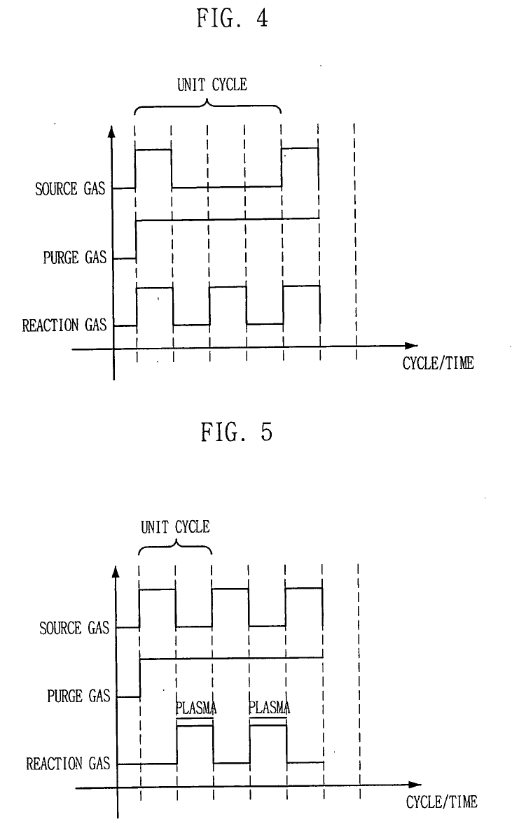

FIG. 4 is a graph illustrating a specific sequence over time of a method for depositing a thin film in accordance with a first embodiment consistent with the present invention using a cyclic chemical vapor deposition (CVD) method.

After a wafer is loaded into a chamber, a purge gas, a source gas, and a reaction gas are simultaneously supplied into the chamber. Because the source gas and the reaction gas react with each other almost instantly as they are supplied into the chamber simultaneously, a deposition rate is high.

Next, while the purge gas continues to be supplied to the chamber, the supply of both the source gas and the reaction gas is discontinued. The purge gas removes, or purges, any remaining reaction byproducts.

Subsequently, while the purge gas continues to be supplied to the chamber, the reaction gas is simultaneously supplied to the chamber.

Next, while the purge gas continues to be supplied to the chamber, the supply of the reaction gas is discontinued, thus completing a unit cycle. The unit cycle is repeatedly performed until a thin film with a desirable thickness is deposited.

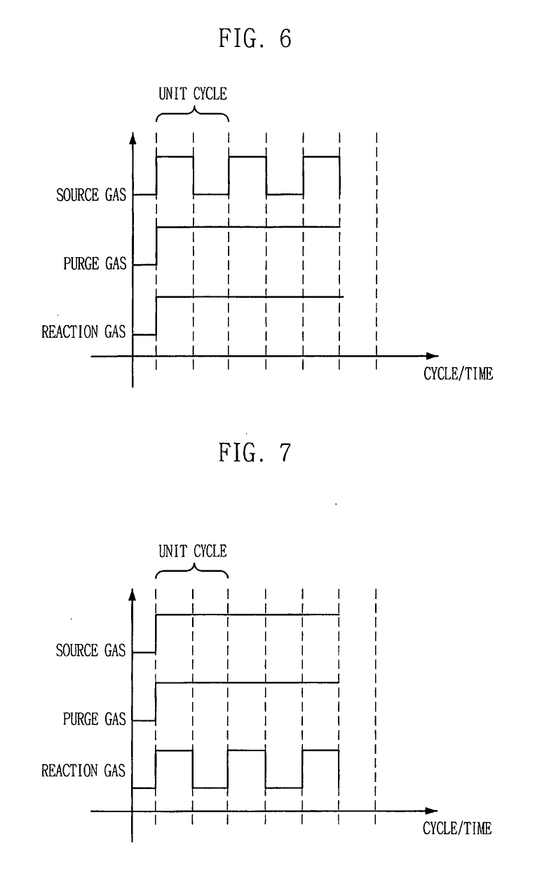

FIG. 5 is a graph illustrating a specific sequence over time of a method for depositing a thin film in accordance with a second embodiment, which is a modified ALD method.

Prior to deposition, a wafer is loaded into a chamber. Then, a source gas and a purge gas are simultaneously supplied into the chamber. Next, as the purge gas continues to be supplied into the chamber, the supply of the source gas is discontinued, and the reaction gas is simultaneously supplied into the chamber. When the reaction gas is supplied into the chamber, plasma may be added. Consistent with this embodiment, as shown in FIG. 5, a unit cycle comprises only two steps. Unlike a typical ALD method, additional purge is not performed after the reaction gas is discontinued. additionally performed; however, the purging is continuously performed while a reaction is being performed.

Because there is reaction gas remaining in the chamber that is not purged, a CVD reaction or a PECVD reaction can occur. Also, because the unit cycle becomes shorter and CVD reaction partially occurs, a deposition rate is higher.

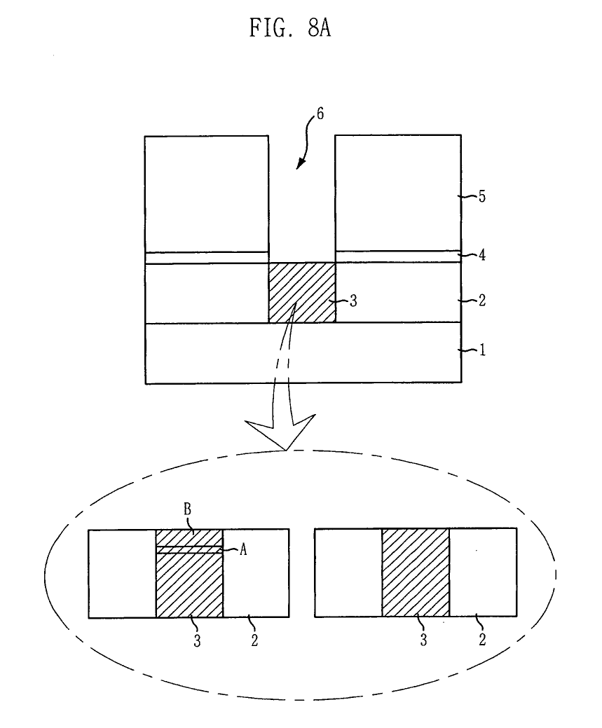

FIG. 6 is a graph illustrating a specific sequence over time of a method for depositing a thin film in accordance with a third embodiment consistent with the present invention using a cyclic CVD method.

Prior to deposition, a wafer is loaded into a chamber. Then a reaction gas and a purge gas are continuously supplied into the chamber, and a source gas is periodically supplied into the chamber.

In this embodiment, a unit cycle comprises a first step of supplying the purge gas, the source gas and the reaction gas simultaneously for a predetermined time and a second step of discontinuing the supply of the source gas.

A CVD reaction occurs when the source gas and the reaction gas are simultaneously supplied to the chamber. In the absence of the source gas, the thin film is annealed to achieve a higher density and a good quality.

The unit cycle comprised by the aforementioned steps is repeated until a thin film having a desired thickness is formed.

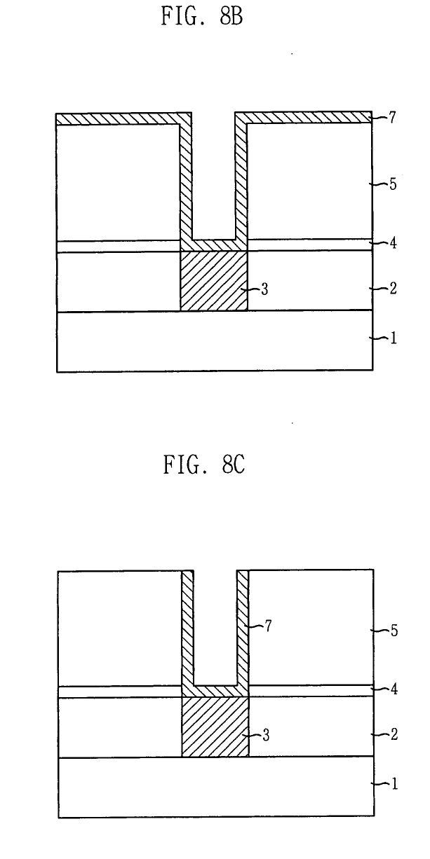

FIG. 7 is a graph illustrating a specific sequence over time of a method for depositing a thin film in accordance with a fourth embodiment consistent with the present invention using a cyclic CVD method.

Prior to deposition, a wafer is loaded into a chamber. Then a source gas and a purge gas are continuously supplied into the chamber, and a reaction gas is periodically supplied into the chamber.

In this embodiment, a unit cycle comprises a first step of supplying the source gas, the purge gas, and the reaction gas simultaneously for a predetermined time, and a second step of discontinuing the supply of the reaction gas.

A CVD reaction occurs when the source gas and the reaction gas are simultaneously supplied to the chamber. In the absence of the reaction gas, the thin film is annealed to achieve a higher density and a good quality.

The unit cycle comprising the aforementioned steps is repeated until a thin film having a desired thickness is formed.

Consistent with the above embodiments, a plasma treatment can be performed as the last step of every unit cycle, or as the last step of a predetermined number of cycles, to improve the quality of the deposited film. When the plasma treatment is performed, the reaction gas may comprise a gas selected from the group consisting of oxygen (O₂), ammonia (NH₃), dihydrogen oxide (H₂O), hydrazine (N₂H₄), Me₂N₂H₂, hydrogen (H₂), and a combination thereof, at a power of approximately 10 W to approximately 1,500 W.

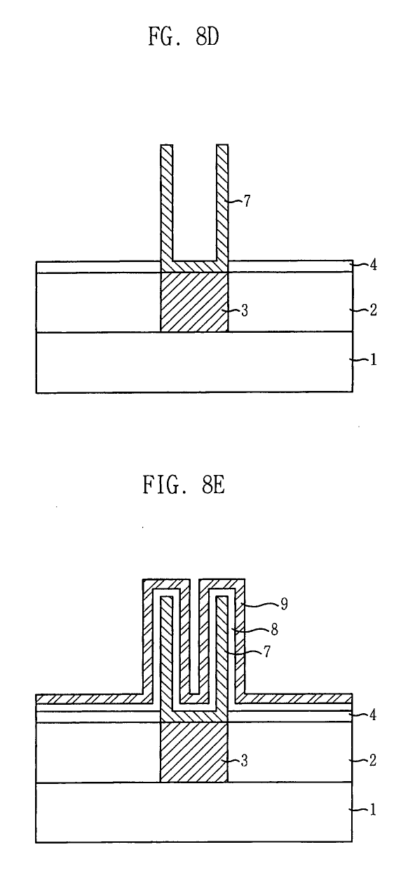

FIGS. 8A to 8E are cross-sectional views illustrating a method for fabricating a capacitor using the method for depositing a thin film explained from FIG. 4 to FIG. 7.

As shown in FIG. 8A, an inter-layer insulation layer 2 is deposited on an upper portion of a substrate 1, which may be a wafer. Substrate 1 may further be prepared to have typical DRAM components such as device isolation layers, word lines and bit lines. A storage node contact plug 3 is formed in inter-layer insulation layer 2 to connect to a portion of substrate 1. The storage node contact plug 3 is recessed a predetermined depth by performing an etch-back process. In one aspect, storage node contact plug 3 comprises polysilicon, and a layer of titanium silicide (TiSi) and a layer of titanium nitride (TiN) are sequentially formed on storage node contact plug 3 and inter-layer insulation layer 2, and then polished by a chemical mechanical polishing (CMP) process, thereby forming a stack structure of a titanium silicide (TiSi) layer A and a titanium nitride (TiN) layer B In another aspect, storage node contact plug comprises a material other than polysilicon, and only a layer of TiN may be deposited and polished to form a TiN layer B on storage node contact layer 3.

TiSi layer A can be used as a plug, and a TiSi plug is exemplified in this embodiment consistent with the present invention.

Next, an etch stop layer 4 and a storage node layer 5 are stacked on an upper portion of the storage node contact plug 3. Herein, the storage node layer 5 is an oxide layer for providing an opening in which a cylinder type storage node will be formed, and the etch stop layer 4 serves as an etch stop layer for preventing a lower structure from being etched during an etching of the storage node layer 5. Etch stop layer 4 may comprise silicon oxide (Si₃N₄) formed by a lower pressure chemical vapor deposition (LPCVD) method, and the storage node layer 5 may comprise borophosphosilicate glass (BPSG), undoped silicate glass (USG), plasma enhanced tetraethyl orthosilicate (PETEOS), or high density plasma (HDP) oxide.

Next, storage node layer 5 and etch stop layer 4 are sequentially etched, thereby forming the aforementioned storage node opening 6 exposing the upper portion of the storage node contact plug 3.

Next, as shown in FIG. 8B, a storage node 7 is formed on the storage node layer 5 and in the opening 6. The storage node 7 is formed by using a mixed method of the ALD method and the CVD method or the cyclic CVD method explained through FIGS. 4 to 7.

Particularly, the mixed method of the ALD method and the CVD method or the cyclic CVD method may improve the deposition rate of the storage node 7 and also ensure sufficient step coverage. The storage node 7 is formed by using a metal layer selected from the group consisting of ruthenium (Ru), platinum (Pt), iridium (Ir) , rhodium (Rh), palladium (Pd), hafnium (Hf), titanium (Ti), tungsten (W), and tantalum (Ta), a nitride metal thereof, and a conductive oxide material can be ruthenium oxide (RuO₂) or iridium oxide (IrO₂).

When the storage node 7 is formed by using a thin film of the above selected material, a source gas uses a source gas of a compound of the aforementioned metal, and a reaction gas uses one selected from the group consisting of O₂, NH₃, N₂O, N₂H₄, (CH₃)₂N₂H₂, H₂, and a combination thereof.

Subsequently, as shown in FIG. 8C, a storage node isolation process forming the cylinder type storage node 7 only inside of the opening 6 is performed.

The storage node isolation process comprises using a CMP process or an etch-back process to remove the storage node 7 formed on an upper surface of the storage node layer 5 but not in the opening 6. Herein, during performing the CMP process or the etch-back process, there is a possibility that impurities such as abrasives or etched particles adhere to the inside of the storage node 7. To prevent impurities from adhering to the inside of storage node 7, photoresist may be filled in opening 6 before the CMP or the etch-back is performed. After CMP or etch-back is performed to expose storage node layer 5, the photoresist is removed.

Meanwhile, after finishing the storage node isolation process, if a dielectric layer is deposited on the storage node layer 5, the storage node 7 becomes a concave type and if the dielectric layer is deposited after removing the storage node layer 5, the storage node 7 becomes the cylinder type. FIG. 8D only shows the cylinder type storage node 7.

As shown in FIG. 8D, the storage node layer 5 is selectively subjected to a wet dip-out process, thereby exposing both inner walls and outer walls of the storage node 7.

The wet dip-out process may be performed using a hydrogen fluoride (HF) solution to etch the storage node layer 5. Etch stop layer 4 beneath the storage node layer 5 which is formed of a material having a high etch selectivity to the storage node layer, acts as an etch stop layer during the etching of storage node layer.

Next, as shown in FIG. 8E, a dielectric layer 8 and a plate electrode 9 are sequentially deposited on the storage node 7. The dielectric layer 8 is formed by using a process selected from a group consisting of a sputtering method, a CVD method, and an ALD method. Post treatment is performed in an atmosphere of O₂, ozone (O₃) or O₂ plasma at temperatures ranging from approximately 200° C. to approximately 500° C.

Dielectric layer 8 includes a material selected from the group consisting of HfO₂, Al₂O₃, zirconium oxide (ZrO₂), lanthanum oxide (La₂O₃), tantalum oxide (Ta₂O₅), titanium oxide (TiO₂), BST(BaSrTiO₃), strontium titanate (SrTiO₃), lead zirconate titanate (PZT), BLT, SPT, Bi₂Ti₂O₇, and a combination thereof. Possible combinations of the above mentioned materials for the dielectric layer 8, i.e., multiple layers, may be HfO₂/Al₂O₃ and HfO₂/Al₂O₃/HfO₂.

Subsequently, the plate electrode 9 on the dielectric layer 8 is formed by using a metal layer selected from a material identical with a storage material, silicon doped with arsenic (As) or phosphorous (P) and a conductive thin film such as TiN formed by the ALD method, the CVD method, the PECVD method, and the method for forming the storage node 7.

As described above, it is possible to minimize degradation in the thin film by controlling the supply of the source gas, the reaction gas and the purge gas when using an ALD or PEALD method of deposition.

The present invention can be applied not only to a storage electrode fabrication of a DRAM capacitor but also to an electrode fabrication of a ferroelectric capacitor of a high density ferroelectric random access memory (FeRAM) using a gate electrode, a barrier metal, and a three dimensional structure.

Consistent with the present invention described above, it is possible to form a thin film having a faster deposition rate than that of a typical ALD method or PEALD method.

Also, during the fabrication of a capacitor of a DRAM device having a size equal to or less than approximately 65 nm, it is possible to fabricate more stable capacitors, thereby greatly improving the throughput and also reducing cost.

Furthermore, during the fabrication of a capacitor of a FeRAM device having a size equal to or less than approximately 150 nm, it is possible to form the FeRAM with a good ferroelectric property and a good fatigue property by employing the embodied methods of the present invention as a lower electrode formation process.

While the present invention has been described with respect to certain preferred embodiments, it will be apparent to those skilled in the art that various changes and modifications may be made without departing from the spirit and scope of the invention as defined in the following claims.

What is claimed is:

1. A method for depositing a thin film on a substrate, comprising:
supplying a source gas, a reaction gas, and a purge gas;
discontinuing the supply of the source gas and the reaction gas;
supplying the reaction gas;
discontinuing the supply of the reaction gas, wherein supplying a source gas, a reaction gas, and a purge gas, discontinuing the supply of the source gas and the reaction gas, supplying the reaction gas, and discontinuing the supply of the reaction gas constitute a unit cycle; and
repeating the unit cycle until a thin film having a desired thickness is formed.

2. The method of claim 1, further comprising performing a plasma treatment on the deposited thin film for every unit cycle.

3. The method of claim 1, further comprising performing a plasma treatment on the deposited thin film on one or more of the repetitions of the unit cycle.

4. The method of claim 1, wherein the thin film is one of a storage node and a plate electrode.

5. The method of claim 1, wherein the thin film includes one selected from the group consisting of ruthenium (Ru), platinum (Pt), iridium (Ir), rhodium (Rh), palladium (Pd), hafnium (Hf), titanium (Ti), tungsten (W), and tantalum (Ta), a nitride metal thereof, and a conductive oxide material.

6. The method of claim 3, wherein performing the plasma treatment comprises using a reaction gas for the plasma treatment selected from the group consisting of oxygen (O₂), ammonia (NH₃), dihydrogen oxide (H₂O), hydrazine (N₂H₄), Me₂N₂H₂, hydrogen (H₂), and a combination thereof.

7. The method of claim 3, wherein performing a plasma treatment comprises performing a plasma treatment using a power ranging from approximately 10 W to approximately 1,500 W.

8. A method for depositing a thin film on a substrate, comprising:
supplying a purge gas, and a source gas;
supplying a reaction gas and discontinuing the supply of the source gas, wherein supplying a purge gas, and a source gas, and supplying a reaction gas and discontinuing the supply of the source gas constitute a unit cycle; and
repeating the unit cycle until a thin film having a desired thickness is formed.

9. The method of claim 8, further comprising performing a plasma treatment on the deposited thin film for every unit cycle.

10. The method of claim 8, further comprising performing a plasma treatment on the deposited thin film on one or more of the repetitions of the unit cycle.

11. The method of claim 8, wherein the step of supplying the reaction gas and discontinuing the supply of the source gas further comprises adding plasma.

12. The method of claim 8, wherein the thin film is one of a storage node and a plate electrode.

13. The method of claim 8, wherein the thin film includes one selected from the group consisting of ruthenium (Ru), platinum (Pt), iridium (Ir), rhodium (Rh), palladium (Pd), hafnium (Hf), titanium (Ti), tungsten (W), and tantalum (Ta), a nitride metal thereof, and a conductive oxide material.

14. The method of claim 10, wherein performing the plasma treatment comprises using a reaction gas for the plasma treatment selected from the group consisting of oxygen (O₂), ammonia (NH₃), dihydrogen oxide (H₂O), hydrazine (N₂H₄), Me₂N₂H₂, hydrogen (H₂), and a combination thereof.

15. The method of claim 10, wherein performing a plasma treatment comprises performing a plasma treatment using a power ranging from approximately 10 W to approximately 1,500 W.

16. A method for depositing a thin film on a substrate, comprising:
supplying a source gas, a reaction gas and a purge gas;
discontinuing the supply of the source gas, wherein supplying a source gas, a reaction gas, and a purge gas, and discontinuing the supply of the source gas constitutes a unit cycle; and
repeating the unit cycle until a thin film having a desired thickness is formed.

17. The method of claim 16, further comprising performing a plasma treatment on the deposited thin film for every unit cycle.

18. The method of claim 16, further comprising performing a plasma treatment on the deposited thin film on one or more repetitions of the unit cycle.

19. The method of claim 16, wherein the thin film is one of a storage node and a plate electrode.

20. The method of claim 16, wherein the thin film includes one selected from the group consisting of ruthenium (Ru), platinum (Pt), iridium (Ir), rhodium (Rh), palladium (Pd), hafnium (Hf), titanium (Ti), tungsten (W), and tantalum (Ta), a nitride metal thereof, and a conductive oxide material.

21. The method of claim 18, wherein performing the plasma treatment comprises using a reaction gas for the plasma treatment selected from the group consisting of oxygen (O₂), ammonia (NH₃), dihydrogen oxide (H₂O), hydrazine (N₂H₄), Me₂N₂H₂, hydrogen (H₂), and a combination thereof.

22. The method of claim 18, wherein performing a plasma treatment comprises performing a plasma treatment using a power ranging from approximately 10 W to approximately 1,500 W.

23. A method for depositing a thin film on a substrate, comprising the steps of:
supplying a source gas, a reaction gas and a purge gas;
discontinuing the supply of the reaction gas, wherein supplying a source gas, a reaction gas and a purge gas, and discontinuing the supply of the reaction gas constitute a unit cycle; and
repeating the unit cycle until a thin film having a desired thickness is formed.

24. The method of claim 23, further comprising performing a plasma treatment on the deposited thin film for every unit cycle.

25. The method of claim 23, further comprising performing a plasma treatment on the deposited thin film on one or more repetitions of the unit cycle.

26. The method of claim 23, wherein the thin film is one of a storage node and a plate electrode.

27. The method of claim 23, wherein the thin film includes one selected from the group consisting of ruthenium (Ru), platinum (Pt), iridium (Ir), rhodium (Rh), palladium (Pd), hafnium (Hf), titanium (Ti), tungsten (W), and tantalum (Ta), a nitride metal thereof, and a conductive oxide material.

28. The method of claim 25, wherein performing the plasma treatment comprises using a reaction gas for the plasma treatment selected from the group consisting of oxygen (O₂), ammonia (NH₃), dihydrogen oxide (H₂O), hydrazine (N₂H₄), Me₂N₂H₂, hydrogen (H₂), and a combination thereof.

29. The method of claim 25, wherein performing a plasma treatment comprises performing the plasma treatment using a power ranging from approximately 10 W to approximately 1,500 W.
